(19) United States
(12) Patent Application Publication
(10) Pub. No.: US 2019/0320147 A1
(43) Pub. Date: Oct. 17, 2019

(54) IMAGING LIGHT ASSEMBLY

(71) Applicant: HON HAI PRECISION INDUSTRY CO., LTD., New Taipei (TW)

(72) Inventors: CHIA-WEI LIU, New Taipei (TW); CHUN-KAI PENG, New Taipei (TW); YING-WEI SHENG, New Taipei (TW)

(21) Appl. No.: 16/204,150

(22) Filed: Nov. 29, 2018

(30) Foreign Application Priority Data
Apr. 13, 2018 (CN) 201810331658.9

(51) Int. Cl. H04N 9/31; G03B 21/14; G02B 7/04; H05K 1/18

(52) U.S. Cl. CPC H04N 9/31; G03B 21/142; G03B 21/145; H05K 2201/10106; H05K 1/182; H05K 2201/10128; G02B 7/04

(57) ABSTRACT

An electronic device includes an imaging light assembly including a display panel, a circuit board, a light source, and a light cover. The light source is mounted and electrically coupled to the circuit board. The light cover is mounted to a rear surface of the display panel and covers the light source. The light source emits light to the light cover. The light cover includes at least one projection lens located between the light cover and the display panel. The at least one projection lens focuses the light emitted by the light source and projects the focused light to the display panel. The focused light projected to the display panel projects an image of a design of the projection lens.

### FIELD

The subject matter herein generally relates to light assemblies, and more particularly to an imaging light assembly of an electronic device.

### BACKGROUND

Generally, images displayed on a display panel of an electronic device are formed by an image pattern within the electronic device illuminated by a light source. An intensity of illumination of the image displayed on the display panel is generally influenced by a quantity of the light sources such as light emitting diodes (LEDs). In order to display the image on the display panel in focus, more LEDs are required or more power is required to be provided to the LEDs.

### BRIEF DESCRIPTION OF THE DRAWINGS

Implementations of the present disclosure will now be described, by way of embodiments, with reference to the attached figures.

FIG. 1 is an exploded, isometric view of an imaging light assembly in accordance with an embodiment of the present disclosure.

FIG. 2 is an isometric view of a light cover of the imaging light assembly in FIG. 1.

FIG. 3 is a cross-sectional view of the imaging light assembly of FIG. 1 showing a light path of light emitted by a light source of the imaging light assembly.

### DETAILED DESCRIPTION

It will be appreciated that for simplicity and clarity of illustration, where appropriate, reference numerals have been repeated among the different figures to indicate corresponding or analogous elements. Additionally, numerous specific details are set forth in order to provide a thorough understanding of the embodiments described herein. However, it will be understood by those of ordinary skill in the art that the embodiments described herein can be practiced without these specific details. In other instances, methods, procedures and components have not been described in detail so as not to obscure the related relevant feature being described. The drawings are not necessarily to scale and the proportions of certain parts may be exaggerated to better illustrate details and features. The description is not to be considered as limiting the scope of the embodiments described herein.

Several definitions that apply throughout this disclosure will now be presented.

The term “coupled” is defined as connected, whether directly or indirectly through intervening components, and is not necessarily limited to physical connections. The connection can be such that the objects are permanently connected or releasably connected. The term “comprising” means “including, but not necessarily limited to”; it specifically indicates open-ended inclusion or membership in a so-described combination, group, series and the like.

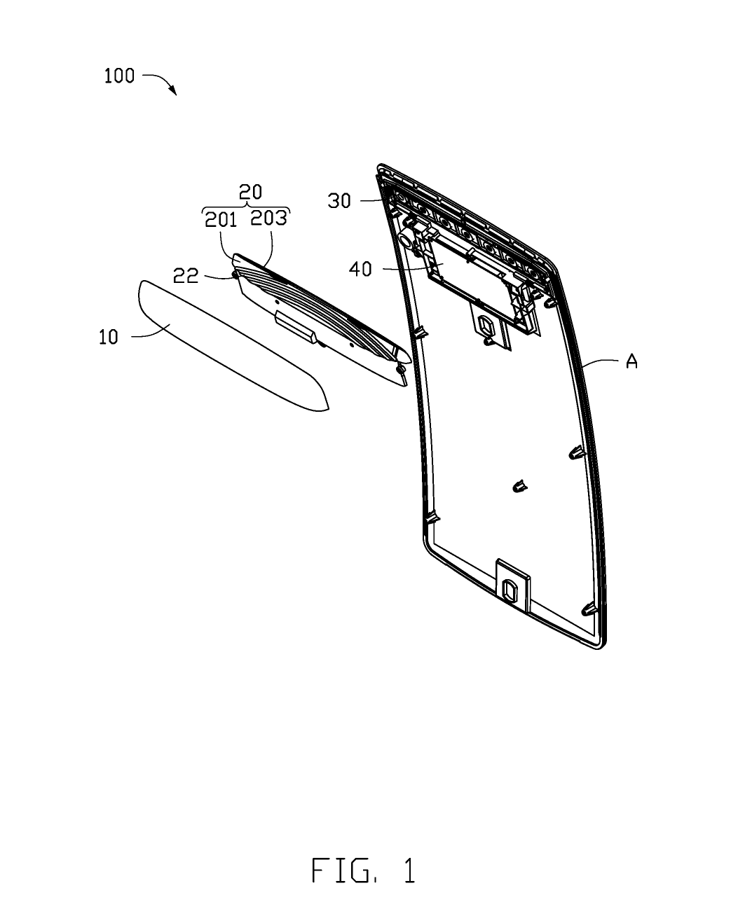

FIG. 1 shows an embodiment of an imaging light assembly 100 including a display panel 10, a light cover 20, a light source 30, and a circuit board 40. The light cover 20 is mounted to a rear surface of the display panel 10 and covers the light source 30. The light source 30 is mounted and electrically coupled to the circuit board 40. The circuit board 40 provides power to the light source 30 to emit light. The light cover 20 includes at least one projection lens 22 located between the light cover 20 and the display panel 10. The projection lens 22 focuses the light emitted by the light source 30 and projects the focused light to the display panel 10. The light projected to the display panel 10 projects an image of a design of the projection lens 22 formed on the light cover 20. The display panel 10, the light cover 20, the light source 30, and the circuit board 40 are mounted in sequence on an electronic device A. The image of the projection lens 22 is projected to the display panel 10 by the light emitted by the light source 30 and focused by the projection lens 22, thereby improving an appearance of the electronic device A.

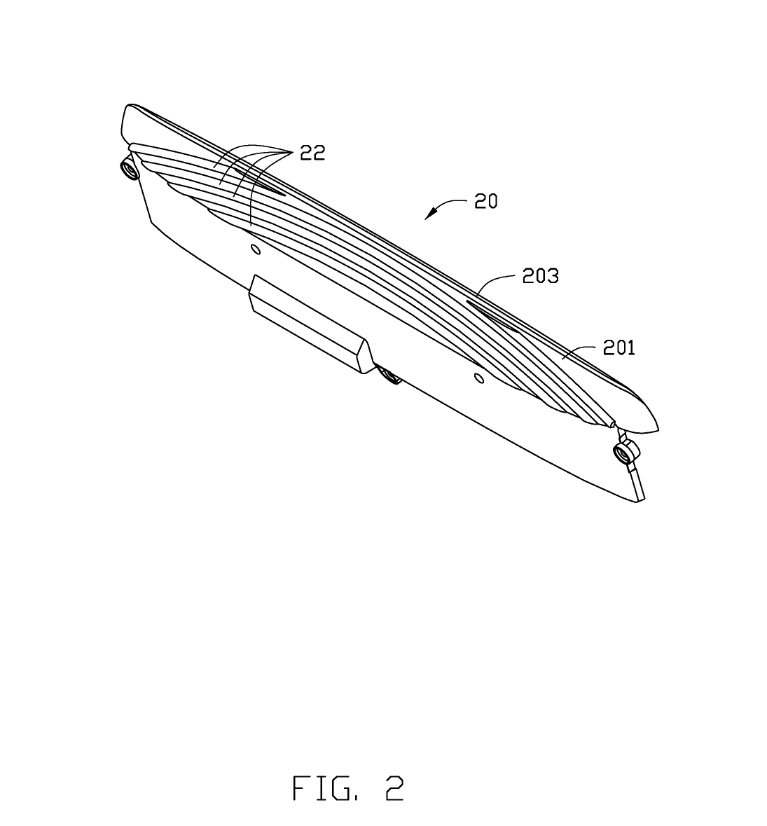

As shown in FIG. 2, the light cover 20 includes a first surface 201 and second surface 203. The first surface 201 and the second surface 203 are on opposite sides of the light cover 20. The first surface 201 is adjacent to the display panel 10, and the second surface 203 is adjacent to the light source 30. The projection lens 22 is formed on the first surface 201. The projection lens 22 protrudes from the first surface 201. The projection lens 22 focuses the light emitted by the light source 30 and projects the focused light to the display panel 10. In one embodiment, the projection lens 22 forms a design on the first surface 201. The projection lens 22 is a long rectangular lens forming the design on the first surface 201 (design not shown). The design is a long arcuate design. The projection lens 22 may be modified in other embodiments to form a different design on the first surface 201 according to requirements. When the projection lens 22 focuses the light emitted by the light source 30, the focused light is projected to the display panel 10 to display the image of the design formed by the projection lens 22. Thus, the image of the design of the projection lens 22 is displayed on the display panel 10 in focus to enhance an appearance of the electronic device A.

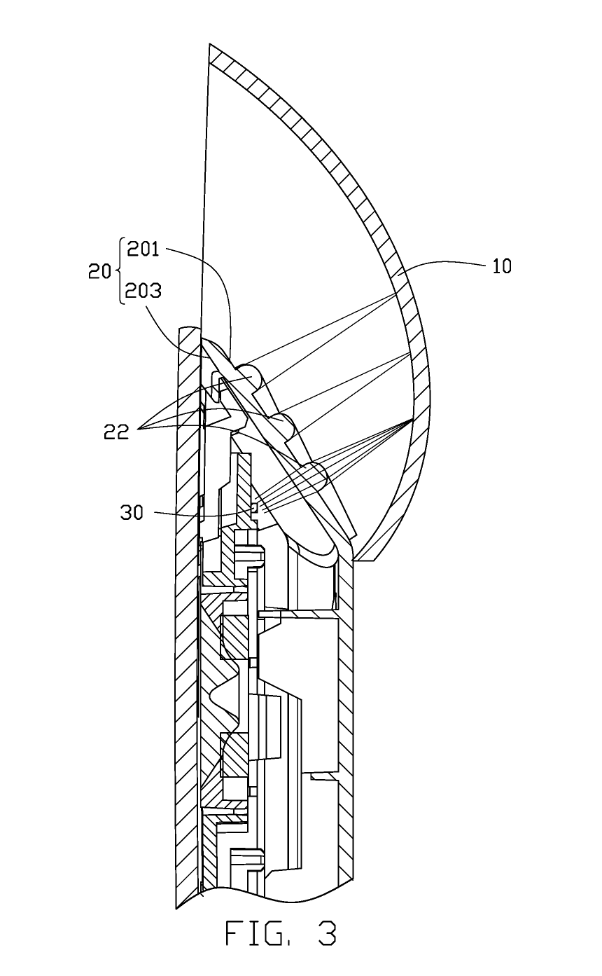

FIG. 3 shows a light path of the light emitted by the light source 30. The light source 30 first emits light to the second surface 203 of the light cover 20, and then the light passes through the first surface 201. The projection lens 22 focuses the light according to the design of the projection lens 22 and projects the focused light to the display panel 10. Thus, the image of the design of the projection lens 22 is displayed on the display panel 10 in focus. Since the image of the design of the projection lens 22 is displayed on the display panel 10 in focus, the light emitted by the light source 30 can have a lower intensity to produce the focused image, thereby reducing a cost of making the imaging light assembly 100.

In one embodiment, the light source 30 includes at least one LED light arranged in series. The intensity of the light emitted by the light source 30 is controlled by connecting more LED lights in series or by adjusting power of the circuit board 40 provided to the light source 30.

The projection lens 22 is integrally formed with the first surface 201 of the light cover 20, so that the design of the projection lens 22 is formed directly on the first surface 201. Thus, the design of the projection lens 22 does not need to be formed separately on the projection lens 22.

The embodiments shown and described above are only examples. Even though numerous characteristics and advantages of the present technology have been set forth in the foregoing description, together with details of the structure and function of the present disclosure, the disclosure is illustrative only, and changes may be made in the detail, including in matters of shape, size and arrangement of the parts within the principles of the present disclosure up to, and including, the full extent established by the broad general meaning of the terms used in the claims.

What is claimed is:

1. An imaging light assembly comprising:
a display panel;
a circuit board;
a light source mounted and electrically coupled to the circuit board;
a light cover mounted to a rear surface of the display panel and covering the light source; wherein:
the light source emits light to the light cover;
the light cover comprises at least one projection lens located between the light cover and the display panel;
the at least one projection lens focuses the light emitted by the light source and projects the focused light to the display panel; and
the focused light projected to the display panel projects an image of a design of the projection lens.

2. The imaging light assembly of claim 1, wherein:
the light cover comprises a first surface and a second surface;
the first surface and the second surface are on opposite sides of the light cover;
the first surface is adjacent to the display panel, and the second surface is adjacent to the light source;
the at least one projection lens is formed on the first surface.

3. The imaging light assembly of claim 2, wherein:
the at least one projection lens protrudes from the first surface; and
the at least one projection lens focuses the light emitted by the light source on the first surface and projects the focused light to the display panel.

4. The imaging light assembly of claim 3, wherein:
the at least one projection lens forms the design on the first surface; and
an image of the design formed on the first surface is projected to the display panel.

5. The imaging light assembly of claim 4, wherein:
the at least one projection lens is a long rectangular lens.

6. The imaging light assembly of claim 5, wherein:
the at least one projection lens is integrally formed with the first surface of the light cover.

7. The imaging light assembly of claim 2, wherein:
the light emitted by the light source is emitted to the second surface of the light cover, passed through the first surface, and then projected to the display panel.

8. The imaging light assembly of claim 7, wherein:
the light source comprises at least one light emitting diode (LED) light arranged in series.

9. The imaging light assembly of claim 1, wherein:
the circuit board provides power to the light source to emit light; and
a brightness of the light emitted by the light source is adjusted by adjusting the power provided by the circuit board.

10. The imaging light assembly of claim 1, wherein:
the display panel, the light cover, the light source, and the circuit board are mounted in sequence on an electronic device.

11. An electronic device comprising an imaging light assembly comprising:
a display panel;
a circuit board;
a light source mounted and electrically coupled to the circuit board;
a light cover mounted to a rear surface of the display panel and covering the light source; wherein:
the light source emits light to the light cover;
the light cover comprises at least one projection lens located between the light cover and the display panel;
the at least one projection lens focuses the light emitted by the light source and projects the focused light to the display panel; and
the focused light projected to the display panel projects an image of a design of the projection lens.

12. The electronic device of claim 11, wherein:
the light cover comprises a first surface and a second surface;
the first surface and the second surface are on opposite sides of the light cover;
the first surface is adjacent to the display panel, and the second surface is adjacent to the light source;
the at least one projection lens is formed on the first surface.

13. The electronic device of claim 12, wherein:
the at least one projection lens protrudes from the first surface; and
the at least one projection lens focuses the light emitted by the light source on the first surface and projects the focused light to the display panel.

14. The electronic device of claim 13, wherein:
the at least one projection lens forms the design on the first surface; and
an image of the design formed on the first surface is projected to the display panel.

15. The electronic device of claim 14, wherein:
the at least one projection lens is a long rectangular lens.

16. The electronic device of claim 15, wherein:
the at least one projection lens is integrally formed with the first surface of the light cover.

17. The electronic device of claim 12, wherein:
the light emitted by the light source is emitted to the second surface of the light cover, passed through the first surface, and then projected to the display panel.

18. The electronic device of claim 17, wherein:
the light source comprises at least one light emitting diode (LED) light arranged in series.

19. The electronic device of claim 11, wherein:
the circuit board provides power to the light source to emit light; and
a brightness of the light emitted by the light source is adjusted by adjusting the power provided by the circuit board.

20. The electronic device of claim 11, wherein:
the display panel, the light cover, the light source, and the circuit board are mounted in sequence on an electronic device.
